(19) United States
(12) Patent Application Publication
(10) Pub. No.: US 2025/0079391 A1
(43) Pub. Date: Mar. 6, 2025

(54) PACKAGING STRUCTURE AND PACKAGING METHOD

(71) Applicant: Semiconductor Manufacturing International (Shanghai) Corporation, Shanghai (CN)

(72) Inventor: Jisong JIN, Shanghai (CN)

(21) Appl. No.: 18/768,680

(22) Filed: Jul. 10, 2024

(30) Foreign Application Priority Data
Aug. 31, 2023 (CN) 202311122861.2

(51) Int. Cl. H01L 23/00; H01L 21/768; H01L 23/528; H01L 25/18

(52) U.S. Cl. CPC H01L 24/73; H01L 21/76898; H01L 23/5283; H01L 23/5286; H01L 24/08; H01L 24/16; H01L 24/32; H01L 25/18; H01L 2224/08145; H01L 2224/16225; H01L 2224/32225; H01L 2224/73204; H01L 2924/15165

(57) ABSTRACT

Packaging structure and packaging method are provided. The packaging structure includes a substrate, including a bonding surface; an interconnection chip, bonded to the bonding surface of the substrate, the interconnection chip including a front side and a back side of a first chip opposite to each other, and the back side of the first chip facing the substrate and being electrically connected to the substrate; and a device chip, bonded to the interconnection chip, the device chip including a front side and a back side of a second chip opposite to each other, the front side of the second chip facing and being electrically connected to the interconnection chip, and the back side of the second chip being electrically connected to the interconnection chip through the front side of the second chip.

### CROSS-REFERENCE TO RELATED APPLICATION

This application claims priority of Chinese Patent Application No. 202311122861.2, filed on Aug. 31, 2023, the entire contents of which are hereby incorporated by reference.

### FIELD OF THE DISCLOSURE

The present disclosure generally relates to the field of semiconductor technology and, more particularly, relates to a packaging structure and a packaging method.

### BACKGROUND

Conventional chip manufacturing technologies are reaching limits thereof in terms of sizes of monolithic chips. However, applications are eager to utilize the latest technology to achieve large-size integrated circuit capabilities, and a pursuit of high-speed and small-volume interconnections between chips presents greater challenges.

One current solution is to use smaller integrated circuits with Si Bridge chips embedded in a silicon substrate to provide chip-to-chip interconnections through the Si Bridge chips, thereby providing heterogeneous chip packaging.

However, a current packaging structure is relatively complex, and an integration between chips still needs to be improved.

### BRIEF SUMMARY OF THE DISCLOSURE

One aspect of the present disclosure provides a packaging structure. The packaging structure includes a substrate, including a bonding surface; an interconnection chip, bonded to the bonding surface of the substrate, the interconnection chip including a front side and a back side of a first chip opposite to each other, and the back side of the first chip facing and being electrically connected to the substrate; and a device chip, bonded to the interconnection chip, the device chip including a front side and a back side of a second chip opposite to each other, the front side of the second chip facing and being electrically connected to the interconnection chip, and the back side of the second chip being electrically connected to the interconnection chip through the front side of the second chip.

Another aspect of the present disclosure provides a packaging method. The packaging method includes providing an interconnection chip, including a front side and a back side of a first chip opposite to each other; providing a device chip, including a front side and a back side of a second chip opposite to each other, bonding the device chip to the interconnection chip, the front side of the second chip facing and being electrically connected to the front side of the first chip, and the back side of the second chip being electrically connected to the interconnection chip through the front side of the second chip; and providing a substrate including a bonding surface, bonding the interconnection chip to the bonding surface of the substrate, and the back side of the first chip facing and being electrically connected to the substrate.

Other aspects of the present disclosure can be understood by a person skilled in the art in light of the description, the claims, and accompanying drawings of the present disclosure.

### BRIEF DESCRIPTION OF THE DRAWINGS

FIG. 1 illustrates a schematic diagram of a packaging structure provided by an embodiment of the present disclosure;

FIG. 2 illustrates a flow chart of a packaging method provided by an embodiment of the present disclosure; and

FIGS. 3-15 illustrate schematic diagrams corresponding to each step in a packaging method provided by an embodiment of the present disclosure.

### DETAILED DESCRIPTION

As described in the background, typically, of two opposite sides of a chip, only a front side of the chip is electrically connected to an external environment. Currently, back side power delivery network (BSPDN) technology is emerging, where interconnection pads (pads) are also formed on a back side of the chip for being electrically connected to the external environment. For example, as described in document 10.1109/TED.2019.2954301, at present, there is no method to electrically lead out the back side of the chip so that both the front and back sides of the chip are electrically connected to the external environment, which hinders efforts to improve a packaging integration.

To solve the above technical problem, a packaging structure is provided by an embodiment of the present disclosure. The packaging structure includes: a substrate, including a bonding surface; an interconnection chip, bonded to the bonding surface of the substrate, including a front side and a back side of a first chip opposite to each other, the back side of the first chip facing and being connected to the substrate; and a device chip, bonded to the interconnection chip, including a front side and a back side of a second chip opposite to each other, the front side of the second chip facing and being electrically connected to the interconnection chip, and the back side of the second chip being electrically connected to the interconnection chip through the front side of the second chip.

In the embodiment, the interconnection chip is bonded to the substrate to realize an electrical connection between the interconnection chip and the substrate. The front side of the second chip of the device chip is bonded to the interconnection chip to establish an electrical connection between the front side of the second chip of the device chip and the interconnection chip, and correspondingly establish an electrical connection between the front side of the second chip of the device chip and the substrate. The back side of the second chip is electrically connected to the interconnection chip through the front side of the second chip, so that the back side of the second chip of the device chip is electrically connected to the substrate, thereby enabling both the front side 200a and the opposite back side 200b of the second chip of the device chip 200 to be electrically connected to the substrate 100. Therefore, through the substrate, the device chip can receive power from either or both front side and back side of the second chip, which improves an integration of the packaging structure. Simultaneously, the front side of the second chip is opposite to the front side of the first chip to establish an electrical connection between the device chip and the interconnection chip, thereby facilitating an easy bonding between the device chip and the interconnection chip and simplifying electrical connection lines.

To make the above objects, features and advantages of the present disclosure to be more obvious and understandable, specific embodiments of the present disclosure will be described in detail below with reference to the accompanying drawings.

FIG. 1 illustrates a schematic diagram of a packaging structure provided by an embodiment of the present disclosure.

The packaging structure includes: a substrate 100, including a bonding surface 100a; an interconnection chip 300, bonded to the bonding surface 100a of the substrate 100, including a front side 300a and a back side 300b of a first chip opposite to each other, the back side 300b of the first chip facing and being connected to the substrate 100; and a device chip 200, bonded to the interconnection chip 300, including a front side 200a and a back side 200b of a second chip opposite to each other, the front side 200a of the second chip facing and being electrically connected to the interconnection chip 300, and the backside 200b of the second chip being electrically connected to the interconnection chip 300 through the front side 200a of the second chip.

The substrate 100 is configured to serve as a basis for a process operation of bonding the interconnected chips 300. Specifically, the bonding surface 100a of the substrate 100 is a process operation platform.

In the embodiment, the substrate 100 includes an interconnection structure layer, and an exposed surface of the interconnection structure layer is the bonding surface 100a.

The interconnection structure layer is configured to bond with the interconnection chip 300 to establish an electrical connection between the substrate and the interconnection chip 300. The interconnection structure layer is further configured to establish an electrical connection between the interconnection chip 300 and the external environment.

In the embodiment, the interconnection structure layer is a redistribution layer structure. Specifically, the redistribution structure may include one or more redistribution layers. In the embodiment, the redistribution structure includes a plurality of redistribution layers, serving as an example for description.

In the embodiment, the substrate 100 is a packaging substrate, specifically a printed circuit board (PCB).

The device chip 200 is configured to establish an electrical connection with the substrate 100 through the interconnection chip 300, thereby forming a packaging structure that executes corresponding functions.

In the embodiment, the front side 200a of the second chip faces and is electrically connected to the interconnection chip 300, and the back side 200b of the second chip is electrically connected to the interconnection chip 300 through the front side 200a of the second chip.

In the embodiment, the interconnection chip 300 is bonded to the substrate 100 to establish an electrical connection between the interconnection chip 300 and the substrate 100. The front side 200a of the second chip of the device chip 200 is bonded to the interconnection chip 300 to establish an electrical connection between the front side 200a of the second chip of the device chip 200 and the interconnection chip 300 and establish an electrical connection between the front side 200a of the second chip of the device chip 200 and the substrate 100. The back side 200b of the second chip is electrically connected to the interconnection chip 300 through the front side 200a of the second chip to correspondingly establish an electrical connection between back side 200b of the second chip of the device chip 200 and the substrate 100, thereby enabling both the front side 200a and the opposite back side 200b of the second chip of the device chip 200 to be electrically connected to the substrate 100. Therefore, through the substrate 100, the device chip 200 can be powered through either or both front side 200a and back side 200b of the second chip 200a, thereby improving an integration of the packaging structure. Simultaneously, the front side 200a of the second chip and the front side 300a of the first chip establish an electrical connection between the device chip 200 and the interconnection chip 300, thereby facilitating an easy bonding between the device chip and the interconnection chip and simplifying electrical connection lines.

Specifically, in the embodiment, devices on the device chip 200 are powered through the back side 200b of the second chip.

In the embodiment, the device chip 200 is bonded to the interconnection chip 300. A power supply to the devices on the device chip 200 is realized through the back side 200b of the second chip, which is conducive to simplifying a circuit and improving the integration of the packaging structure.

Specifically, in the embodiment, signal electrical connections are made to the devices on the device chip 200 through the front side 200a of the second chip. Compared with a solution in which power supply lines and signal lines are both electrically connected from the front side of the second chip of the first device chip, the present solution is conducive to reducing mutual interferences between the power supply lines and the signal lines, allowing greater design flexibility for the power supply lines, which are electrically connected through the backside 200b of the second chip. The present solution increases available space, and reduces a resistance of the power supply line, thereby lowering a probability that voltage drop affects device performance due to excessive resistance of the power supply lines and ultimately enhancing the device performance. Therefore, the signal lines electrically connected through the second chip front side 200a also have a larger formation space, so that the devices on the device chip 200 can achieve a better working performance.

In the embodiment, the devices on the device chip 200 are electrically connected to the back side of the second chip 200b to supply power through the back side of the second chip 200b.

In the embodiment, the device chip 200 includes a backside interconnection layer 220 on the back side 200b side of the second chip. The backside interconnection layer 220 is electrically connected to the interconnection chip 300. The backside interconnection layer 220 is also electrically connected to the devices on device chip 200.

The backside interconnection layer 220 is configured to establish electrical connections between the devices on the device chip 200 and the external environment through back side 200b of the second chip. The backside interconnection layer 220 is further configured to establish an electrical connection between the interconnection chip 300 and the external environment.

It should be noted that in the embodiment, a through-silicon-via (TSV) structure is configured to electrically connect the backside interconnection layer 220 to the devices on the device chip 200, which is conducive to making electrical transmission more direct and rapid.

In the embodiment, the device chip 200 further includes a substrate 210 and a device layer 230 on the substrate 210. The device layer 230 is on a side of the substrate 210 facing the interconnection chip 300.

The device layer 230 is configured to form devices on the device chip 200. The device layer 230 is on the side of the substrate 210 facing the interconnection chip 300, i.e., a side facing the front side 200a of second chip. The above arrangement leaves space for forming the back interconnection layer 220 on the other side of the substrate 210. Therefore, the backside interconnection layer 220 formed on the other side of the substrate 210 can face the back side 200b of the second chip to realize backside power supply to devices in the device layer 230.

Specifically, in the embodiment, during a forming process of the packaging structure, the device chip 200 includes the substrate 210 and the device layer 230 on the substrate 210. The substrate 210 is on the back side 200b of the second chip, and the device layer 230 is on the front side 200a of the second chip. The substrate 210 serves as a process platform for forming the device layer 230 and the backside interconnection layer 220. The substrate 210 undergoes a back side thinning process, removing part of a thickness of the substrate 210 through the back side 200b of the second chip. After the back side of the substrate 210 is thinned, the backside interconnection layer 220 is formed on the remaining substrate 210.

Accordingly, in the embodiment, the backside interconnection layer 220 is on a side of the substrate 210 facing a carrier board 500, i.e., a side facing the backside 200b of the second chip.

In the embodiment, the first interconnection structures 410 are formed on the front side 200a of the second chip of the device chip 200. The backside interconnection layer 220 of the device chip 200 is electrically connected to the interconnection chip 300 through the first interconnection structures 410.

The first interconnection structures 410 are configured to establish electrical connections between the backside interconnection layer 220 and the external environment. The first interconnection structures 410 are on the front side 200a of the second chip, so that the first interconnection structures 410 can be electrically connected to the interconnection chip 300 through the front side 200a of the second chip. Accordingly, the backside interconnection layer 220 is electrically connected to the interconnection chip 300 through the first interconnection structures 410.

In the embodiment, the backside interconnection layer 220 is electrically connected to the front side 200a of the second chip of the device chip 200 through a wiring of the first interconnection structures 410. Subsequently, the backside interconnection layer 220 is electrically connected to the substrate 100 through the front side 200a of the second chip. The wiring of the first interconnection structures 410 enhances an accuracy of electrical transmission.

It should be noted that, in the embodiment, the first interconnection structure 410 includes a through-silicon-via (TSV) structure, which is conducive to making an electrical transmission more direct and rapid.

In the embodiment, a material of the first interconnection structure 410 is a metal material including one or more of copper, aluminum, tungsten, cobalt, nickel, titanium, tantalum, titanium nitride, and tantalum nitride.

The interconnection chip 300 is configured to electrically connect with the device chip 200 to establish a basic circuit structure between the interconnection chip 300 and the device chip 200. The interconnection chip 300 is further configured to electrically connect with the substrate 100, thereby establishing an electrical connection between the interconnection chip 300 and the external environment, and consequently establishing an electrical connection between the device chip 200 and the external environment.

In the embodiment, bonding the interconnection chip 300 to the device chip 200 increases a total thickness of the interconnection chip 300 when the device chip 200 is bonded to the substrate 100, which is conducive to increasing a bonding strength of the device chip 200, and realizing a bonding of the device chip 200 to the substrate 100 for backside power supply. In the embodiment, devices are also formed in the interconnection chip 300 to establish an electrical connection between the device chip 200 and the interconnection chip 300, which enhances a diversity of circuit structures and improves an applicability of the packaging structure.

It should be noted that establishing the electrical connection between the device chip 200 and the interconnection chip 300 enables a formation of more complex circuit structures, thereby enhancing the performance of the packaging structure, such as increasing the data storage capacity of the packaging structure.

In the embodiment, second interconnection structures 420 penetrating the interconnection chip 300 are formed in the interconnection chip 300. The second interconnection structures 420 are electrically connected to the first interconnection structures 410, and the second interconnection structures 420 are further electrically connected to the substrate 100.

The second interconnection structures 420 serve as electrical connection structures. The second interconnection structures 420 are electrically connected to the first interconnection structures 410 to establish electrical connections between the second interconnection structures 420 and the backside interconnection layer 220. The second interconnection structures 420 are further electrically connected to the substrate 100 to establish electrical connections between the backside interconnection layer 220 and the substrate 100, thereby realizing a backside power supply to the device chip 200 through the backside interconnection layer 220.

In the embodiment, a material of the second interconnection structures 420 is a metal material including one or more of copper, aluminum, tungsten, cobalt, nickel, titanium, tantalum, titanium nitride, and tantalum nitride.

In the embodiment, the interconnection chip 300 may further include devices electrically connected to the substrate 100. The devices on the interconnection chip 30 may further be electrically connected to the devices on the device chip 200 to establish electrical connections between the devices of the interconnection chip 300 and the external environment, thereby realizing basic circuit functions of the interconnection chip 300, and correspondingly realizing a substrate circuit between the devices on the interconnection chip 300 and the devices on the device chip 200.

In the embodiment, the first interconnection structure 410 includes a first bonding pad 411 exposed by the front side 200a of the second chip. The second interconnection structure 420 includes a second bonding pad 421 on a side facing away from the bonding surface 100a and exposed by the interconnection chip 300. The first bonding pads 411 are bonded to the second bonding pads 421.

The first bonding pads 411 and the second bonding pads 421 are configured to bond the device chip 200 to the interconnection chip 300 and establish electrical connections between the first interconnection structures 410 and the second interconnection structures 420.

In the embodiment, the packaging structure further includes interconnection pads 430 on the back side 300b of the first chip, which are electrically connected to the second interconnection structures 420.

The interconnection pads 430 are configured to bond the interconnection chip 300 with the substrate 100 and establish electrical connections between the interconnection chip 300 and the substrate 100.

In other embodiments, the second interconnection structures may penetrate through the interconnection chip and include interconnection pads exposed by the back side of the first chip.

In the embodiment, the packaging structure further includes the carrier board 500 bonded to the back side 200b of the second chip of the device chip 200.

The carrier board 500 is configured to shield the back side 200b of the second chip of the device chip 200 and to reinforce the device chip 200 to facilitate bonding the device chip 200 and the interconnection chip 300 to the substrate 100.

In the embodiment, the carrier board 500 is bonded to the back side 200b of the second chip of the device chip 200, which reinforces the device chip and improves a mechanical strength of the device chip, and makes the device chip 200 easy to bond, thereby facilitating a powering of the device chip 200 through the substrate 100 from either or both sides of the front side 200a and the back side 200b of the second chip.

In the embodiment, the carrier plate 500 is a light-sheet wafer.

In the embodiment, the packaging structure also includes a bonding dielectric layer 510 between the device chip 200 and the carrier board 500. The device chip 200 and the carrier board 500 are bonded through the bonding dielectric layer 510.

The bonding dielectric layer 510 is configured to bond the device chip 200 to the carrier board 500, which is conducive to enhancing a bonding effect.

In the embodiment, the packaging structure further includes conductive bumps 110 located between the interconnection chip 300 and the substrate 100 and electrically connected to the interconnection chip 300 and the substrate 100.

The conductive bumps 110 are configured to establish electrical connections between the substrate 100 and the interconnection chip 300.

In the embodiment, a material of the conductive bumps 110 includes one or more tin, copper, aluminum, tungsten, cobalt, nickel, titanium, tantalum, titanium nitride and tantalum nitride. For example, the conductive bumps 110 are made of tin.

For example, the conductive bump 110 can be controlled collapse chip connection (C4), known for excellent electrical and thermal properties thereof. Under a same pitch of the first conductive bumps, and an I/O value of the conductive bump 110 can be very high and is not limited by a size of a rewiring structure. In addition, the conductive bumps 110 are suitable for mass production and greatly reduce the size and weight.

In other embodiments, the conductive bumps may also be micro-bumps (pBumps).

In the embodiment, the packaging structure further includes a sealing layer 130 that fills in gaps between adjacent conductive bumps 110 and covers the conductive bumps 110.

The sealing layer 130 is configured to provide sealing between the device chip 200 and the substrate 100, as well as between the interconnection chip 300 and the substrate 100. The sealing layer 130 is further configured to seal the conductive bumps 110.

It should be noted that in an actual process, the embodiment is particularly applicable when a buried power rail (BPR) structure and a power delivery network (PDN) structure are used, which require high chip size and integration.

In the embodiment, the conductive bumps 110 described above are the first conductive bumps 110. The packaging structure further includes second conductive bumps 120 on a surface of the substrate 100 facing away from the bonding surface 100a. The second conductive bumps 120 are configured to establish electrical connections between the package structure and an external circuit.

The electrical connections between the packaging structure and the external circuit is established through the second conductive bumps 120, enabling electrical connections between the device chip 200 and the external circuit and electrical connections between the interconnection chip 300 and the external circuit.

In the embodiment, a material of the second conductive bump 120 includes one or more of tin, copper, aluminum, tungsten, cobalt, nickel, titanium, tantalum, titanium nitride and tantalum nitride. For example, the material of the second conductive bump 120 is tin.

For example, the second conductive bump 120 can be controlled collapse chip connection (C4), known for excellent electrical and thermal properties thereof. Under a similar pitch of the first conductive bumps, and I/O value of the second conductive bumps 120 can be very high and is not limited by a size of a rewiring structure. In addition, the second conductive bumps 120 are suitable for mass production and greatly reduces the size and weight.

In other embodiments, the second conductive bump may also be a ball grid array (BGA) structure.

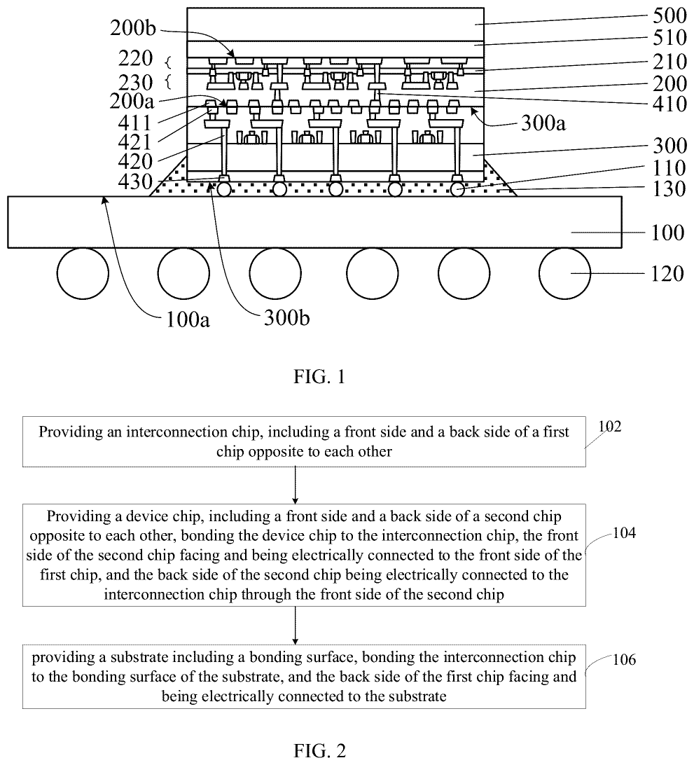

FIG. 2 illustrates a flow chart of a packaging method provided by an embodiment of the present disclosure. In the embodiment, the packaging method includes the following steps.

102: providing an interconnection chip, including a front side and a back side of a first chip opposite to each other.

104: providing a device chip, including a front side and a back side of a second chip opposite to each other, bonding the device chip to the interconnection chip, the front side of the second chip facing and being electrically connected to the front side of the first chip, and the back side of the second chip being electrically connected to the interconnection chip through the front side of the second chip.

106: providing a substrate including a bonding surface, bonding the interconnection chip to the bonding surface of the substrate, and the back side of the first chip facing and being electrically connected to the substrate.

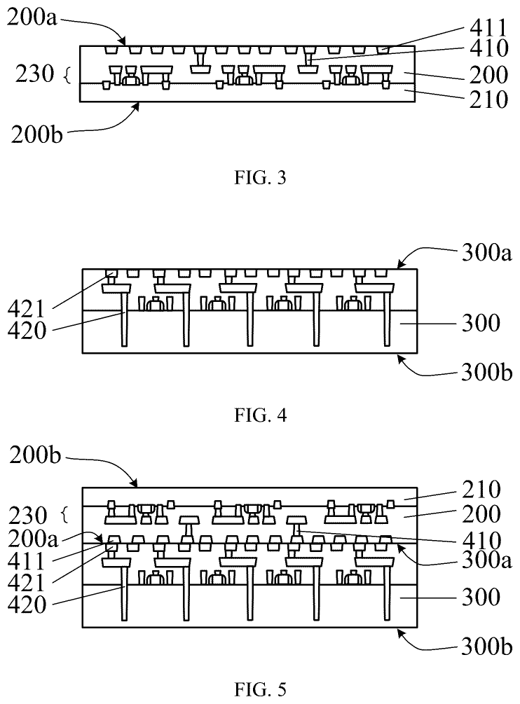

FIGS. 3-15 illustrate schematic diagrams corresponding to each step in a packaging method provided by an embodiment of the present disclosure.

Referring to FIG. 3, The packaging method includes providing a device chip 200 including a front side 200a and a back side 200b of a second chip opposite to each other.

The device chip 200 is configured to be electrically connected to the substrate to form a packaging structure with corresponding functions. Both a front side 200a and a back side 200b of a second chip are utilized for electrical connections with an external environment.

Subsequently, power is supplied to the devices on the device chip 200 through the back side 200b of the second chip, that is, a back side of the device chip.

In the embodiment, in providing the device chip 200, the device chip 200 includes a substrate 210 and a device layer 230 on the substrate 210. The substrate 210 is on the back side 200b of the second chip, and the device layer 230 is on the front side 200a of the second chip.

The substrate 210 serves as a process platform for forming the device layer 230 and the backside interconnection layer 220.

In the embodiment, the substrate 210 is on the back side 200b of the second chip, and the device layer 230 is on the front side 200a of the second chip. Therefore, the substrate 210 on the back side 200b of the second chip leaves a space for forming the backside interconnection layer, so that the subsequently formed backside interconnection layer is on a side of the substrate 210 facing the backside 200b of the second chip.

In the embodiment, in providing the device chip 200, first interconnection structures 410 on the front side 200a of the second chip are formed in the device chip 200.

The backside interconnection layer of the device chip 200 is electrically connected to the interconnection chip 300 through the first interconnection structures 410.

The first interconnection structures 410 are configured to establish electrical connections with the backside interconnection layer, thereby establishing an electrical connection between the backside interconnection layer and the external environment. The first interconnection structures 410 on the front side 200a of the second chip can be electrically connected to the substrate through the front side 200a of the second chip, thereby establishing electrical connections between the backside interconnection layer and the substrate through the first interconnection structures 410.

It should be noted that in the embodiment, the first interconnection structure 410 includes a through-silicon-via (TSV) structure, which is conducive to making electrical transmission more direct and rapid.

In the embodiment, a material of the first interconnection structure 410 is a metal material including one or more of copper, aluminum, tungsten, cobalt, nickel, titanium, tantalum, titanium nitride, and tantalum nitride.

In the embodiment, in providing the device chip 200, the first interconnection structure 410 includes a first bonding pad 411 exposed by the front side 200a of the second chip.

The first bonding pads 411 are configured to bond the device chip 200 and the interconnection chip 300 with the second bonding pads 421 and are further configured to establish electrical connections between the first interconnection structures 410 and the second interconnection structures 420.

Referring to FIG. 4, the packaging method further includes providing an interconnection chip 300 including a front side 300a and a back side 300b of a first chip opposite to each other.

The interconnection chip 300 is configured to bond with the device chip 200 to establish electrical connections with both the device chip 200 and the substrate through the device chip 200.

In the embodiment, in providing the interconnection chip 300, second interconnection structures 420 are formed in the interconnection chip 300 and extend from the front side 300a of the first chip to the back side 300b of the first chip.

The second interconnection structures 420 are configured to subsequently establish electrical connections between the device chip 200 and the substrate.

In the embodiment, a material of the second interconnection structure 420 is a metal material including one or more of copper, aluminum, tungsten, cobalt, nickel, titanium, tantalum, titanium nitride, and tantalum nitride.

In the embodiment, in providing the interconnection chip 300, the second interconnection structure 420 includes a second bonding pad 421 exposed by the front side 300a of the first chip.

The second bonding pads 421 are configured to subsequently bond the device chip 200 and the interconnection chip 300 with the first bonding pads 411 and are further configured to subsequently establish electrical connections between the first interconnection structures 410 and the second interconnection structures 420.

Referring to FIGS. 4 to 6, the device chip 200 is bonded to the interconnection chip 300. The front side 200a of the second chip is electrically connected to the opposite front side 300a of the first chip. The back side 200b of the second chip is electrically connected to the interconnection chip 300 through the front side 200a of the second chip.

The interconnection chip 300 is electrically connected to the device chip 200 to establish a basic circuit structure between the interconnection chip 300 and the device chip 200. The interconnection chip 300 is further configured to electrically connect with the substrate, thereby establishing an electrical connection between the interconnection chip 300 and the external environment.

In the embodiment, the interconnection chip 300 is bonded to the substrate to establish an electrical connection between the interconnection chip 300 and the substrate. The front side 200a of the second chip of the device chip 200 is bonded to the interconnection chip 300 to establish an electrical connection between the front side 200a of the second chip of the device chip 200 and the interconnection chip 300, and accordingly establish an electrical connection between the front side 200a of the second chip of the device chip 200 and the substrate. The back side 200b of the second chip is electrically connected to the interconnection chip 300 through the front side 200a of the second chip, and an electrical connection is correspondingly established between back side 200b of the second chip of the device chip 200 and the substrate, thereby enabling both the front side 200a and the opposite back side 200b of the second chip of the device chip 200 to be electrically connected to the substrate. Therefore, through the substrate, the device chip 200 can be powered through either or both front side and back side of the second chip, thereby enhancing an integration of the packaging structure. The front side 200a of the second chip is opposite to the front side 300a of the first chip to establish an electrical connection between the device chip 200 and the interconnection chip 300, thereby facilitating an easy bonding between the device chip 200 and the interconnection chip 300 and simplifying electrical connection lines.

In the embodiment, in electrically connecting back side 200b of the second chip to the interconnection chip 300 through the front side 200a of the second chip, the devices on the device chip 200 are electrically connected to back side 200b of the second chip to supply power through the back side 200b of the second chip.

In the embodiment, the device chip 200 is bonded to the interconnection chip 300, enabling power supply to the devices on the device chip 200 through the back side 200b of the second chip, which is conducive to simplifying the circuit and improving the integration of the packaging structure.

Specifically, in the embodiment, power is supplied to the devices on the device chip 200 through the back side 200b of the second chip, and signal electrical connections to the devices on the device chip 200 are established through the front side 200a of the second chip. Compared with a solution in which power supply lines and signal lines are both electrically connected from the front side of the second chip of the first device chip, the present solution is conducive to reducing mutual interferences between the power supply lines and the signal lines, allowing greater design flexibility for the power supply lines, which are electrically connected through the backside 200b of the second chip. The present solution increases available space, and reduces a resistance of the power supply line, thereby lowering a probability that voltage drop affects device performance due to excessive resistance of the power supply lines and ultimately enhancing the device performance. Therefore, the signal lines electrically connected through the second chip front side 200a also have a larger formation space, so that the devices on the device chip 200 can achieve a better working performance.

Referring to FIG. 5, the front side 200a of the second chip of the device chip 200 is bonded to the front side 300a of the first chip of the interconnection chip 300.

In the embodiment, in bonding the device chip 200 to the interconnection chip 300, the first interconnection structures 410 are electrically connected to the interconnection chip 300.

The first interconnection structures 410 are electrically connected to the interconnection chip 300. The first interconnection structures 410 are electrically connected to the devices on the device chip 200 and are configured to establish electrical connections between the devices and the external environment through the electrical connections between the first interconnection structures 410 and the interconnection chip 300.

In the embodiment, in bonding the device chip 200 to the interconnection chip 300, the second interconnection structures 420 are electrically connected to the first interconnection structures 410.

The second interconnection structures 420 are electrically connected to the first interconnection structures 410, and are configured to establish electrical connections between the backside interconnection layer and the second interconnection structure 420 through the first interconnection structures 410, and subsequently establish electrical connections between the backside interconnection layer and the substrate, thereby providing a backside power supply to the devices on the device chip 200 through the backside interconnection layer.

In the embodiment, in bonding the device chip 200 to the interconnection chip 300, the first bonding pads 411 are bonded to the second bonding pads 421.

The first bonding pads 411 and the second bonding pads 421 are configured to bond the device chip 200 to the interconnection chip 300 and are further configured to establish electrical connections between the first interconnection structures 410 and the second interconnection structures 420.

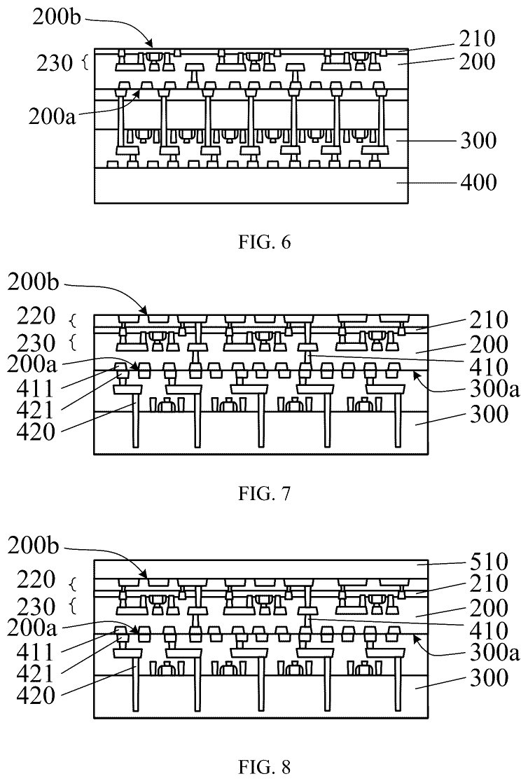

Referring to FIG. 6, the electrically connecting back side 200b of the second chip to the interconnection chip 300 through the front side 200a of the second chip includes: after the front side 200a of the second chip of the device chip 200 is bonded to the front side 300a of the first chip of the interconnection chip 300, performing a backside thinning process on the device chip 200 through the back side 200b of the second chip.

The front side 200a of the second chip of the device chip 200 faces and is bonded to the interconnection chip 300, exposing the back side 200b of the second chip in preparation for a subsequent backside thinning processing.

The interconnection chip 300 is configured to provide support for the backside thinning of the device chip 200.

In the embodiment, the device chip 200 undergoes the backside thinning process through the back side 200b of the second chip to remove excess substrate 210 material.

A part of a thickness of the substrate 210 is removed, and a remaining part of the thickness of the substrate 210 serves as a process platform for a subsequent formation of the backside interconnection layer.

Referring to FIG. 7, after the backside thinning process is performed, a backside interconnection layer 220 is formed on the back side 200b of the second chip. The backside interconnection layer 220 is electrically connected to the devices on the device chip 200. The backside interconnection layer 220 is also electrically connected to the interconnection chip 300.

The backside interconnection layer 220 is configured to establish electrical connections between the devices in the device chip 200 and the external environment through the backside 200b of the second chip.

It should be noted that in the embodiment, the back interconnection layer 220 is electrically connected to the devices on the device chip 200 through a through-silicon-via (TSV) structure, which is conducive to making electrical transmission more direct and rapid.

In the embodiment, in forming the backside interconnection layer 220 on the back side 200b of the second chip, the backside interconnection layer 220 is formed on a side of the substrate 210 facing the backside 200b of the second chip.

The backside interconnection layer 220 is on a side of the substrate 210 facing the backside 200b of the second chip, so that the backside interconnection layer 220 can subsequently provide a backside power supply to the devices on the device chip 200.

In the embodiment, in forming the backside interconnection layer 220 on the back side 200b of the second chip, the backside interconnection layer 220 is electrically connected to the first interconnection structures 410.

The backside interconnection layer 220 is electrically connected to the first interconnection structures 410, so that the backside interconnection layer 220 is electrically connected to the substrate through the first interconnection structures 410.

In the embodiment, the backside interconnection layer 220 is electrically connected to the interconnection chip 300 through a wiring of the first interconnection structures 410 and is subsequently electrically connected to the substrate through the interconnection chip 300. The wiring of the first interconnection structures 410 is conducive to making electrical transmission more accurate.

Referring to FIG. 8, a bonding dielectric layer 510 is formed on back side 200b of the second chip of the device chip 200. The bonding dielectric layer 510 is configured to subsequently bond the device chip 200 to the carrier board.

Referring to FIG. 9, after the device chip 200 is bonded to the interconnection chip 300, and the back side 200b of the second chip is electrically connected to the interconnection chip 300 through the front side 200a of the second chip. Before the back side 300b of the first chip forms interconnection pads that is electrically connected to internal interconnection structures, the packaging method further includes providing a carrier board 500.

The carrier board 500 is configured to provide support when the conductive bumps are subsequently formed on the interconnection chip 300 and to shield the back side 200b of the second chip of the device chip 200. The carrier board 500 is further configured to reinforce the device chip 200 and facilitate bonding the device chip 200 and the interconnection chip 300 to the substrate 100.

In the embodiment, the carrier plate 500 is a light-sheet wafer.

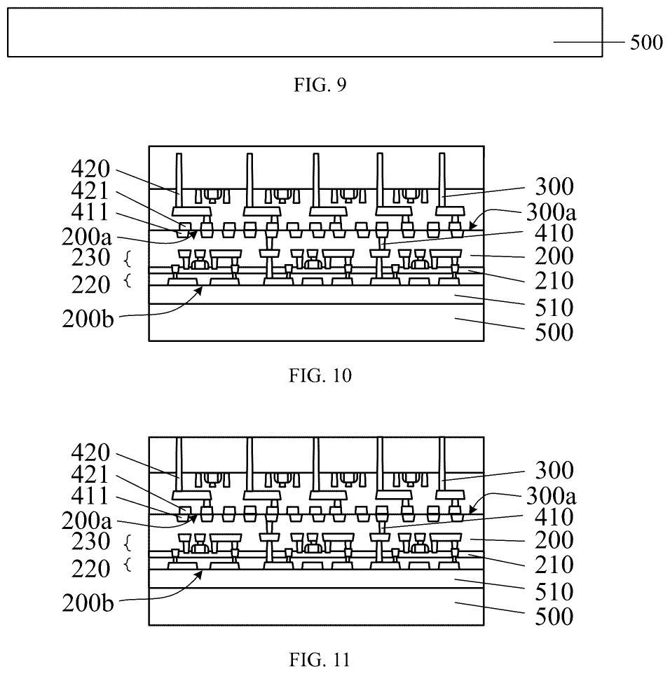

Referring to FIG. 10, the carrier board 500 is bonded to the back side 200b of the second chip of the device chip 200.

In the embodiment, the carrier plate 500 is bonded on the back side 200b of the second chip of the device chip 200, which is conducive to reinforcing the device chip, improving a mechanical strength of the device chip 200, making the device chip 200 easy to bond, thereby facilitating a powering of the device chip 200 through the substrate 100 through either or both front side 200a and back side 200b of the second chip.

In the embodiment, in bonding the carrier board 500 to the back side 200b of the second chip of the device chip 200, the device chip 200 is bonded to the carrier board 500 through the bonding dielectric layer 510.

The bonding dielectric layer 510 is configured to bond the device chip 200 to the carrier board 500, which is conducive to enhancing a bonding effect.

Referring to FIGS. 10 and 11, before the interconnection chip 300 is subsequently bonded to the bonding surface of the substrate, the packaging method further includes: forming interconnection pads 430 electrically connected to the second interconnection structures 420 on the back side 300b of the first chip.

The interconnection pads 430 are configured to bond the interconnection chip 300 to the substrate and establish electrical connections between the interconnection chip 300 and the substrate.

Referring to FIG. 11, the establishing electrical connections between the interconnection pads 430 and the second interconnection structures 420 on the back side 300b of the first chip includes: performing a backside thinning process on the back side of the first chip 300b so that the second interconnection structures 420 are exposed.

The first chip backside 300b undergoes the backside thinning process to expose the second interconnection structures 420 in preparation for forming the interconnection pads electrically connected to the second interconnection structures 420.

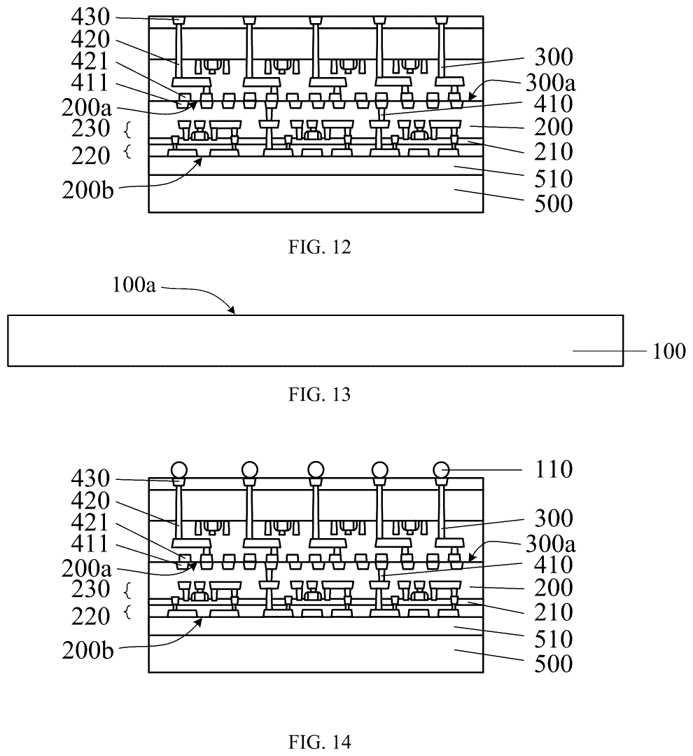

Referring to FIG. 12, the interconnection pads 430 are formed on exposed surfaces of the second interconnection structures 420.

The interconnection pads 430 are formed on the exposed surface of the second interconnection structures 420 to establish electrical connections between the interconnection pad 430 and the second interconnection structures 420.

In other embodiments, the second interconnection structures may penetrate through the interconnection chip and may include the interconnection pads exposed by the back side of the first chip.

Referring to FIG. 13, the packaging method includes providing a substrate 100 including a bonding surface 100a. The substrate 100 is configured to serve as a process base for bonding the device chip 200. Specifically, the bonding surface 100a of the substrate 100 is a processing platform.

In the embodiment, the substrate 100 includes an interconnection structure layer, and an exposed surface of the interconnection structure layer is the bonding surface 100a.

The interconnection structure layer is configured to subsequently bond with the device chip 200 to establish electrical connections with the device chip 200. The interconnection structure layer is further configured to establish electrical connections between the device chip 200 and the external environment.

In the embodiment, the interconnection structure layer is a redistribution structure. Specifically, the redistribution structure may include one or more redistribution layers. In the embodiment, the redistribution structure includes a plurality of redistribution layers as an example for description.

In the embodiment, the substrate 100 is a packaging substrate, specifically a printed circuit board (PCB).

Referring to FIGS. 13 and 14, the interconnection chip 300 is bonded to the bonding surface 100a of the substrate 100. The back side 300b of the first chip faces and is electrically connected to the substrate 100.

After the device chip 200 is bonded to the interconnection chip 300, the interconnection chip 300 is bonded to the substrate 100 to form a packaging structure to execute corresponding functions.

In the embodiment, in bonding the interconnection chip 300 to the substrate 100, the second interconnection structures 420 is electrically connected to the substrate 100.

The second interconnection structures 420 are electrically connected to the substrate 100, thereby establishing electrical connections between the first interconnection structures 410 and the substrate 100, and correspondingly establishing electrical connections between the backside interconnection layer 220 and the substrate 100.

In the embodiment, bonding the device chip 200 to the substrate 100 includes: forming conductive bumps 110 on the front side 200a of the second chip of the device chip 200, or on the bonding surface 100a.

The conductive bumps 110 are configured to establish electrical connections between the substrate 100 and the device chip 200.

In the embodiment, a material of the conductive bumps 110 includes one or more tin, copper, aluminum, tungsten, cobalt, nickel, titanium, tantalum, titanium nitride and tantalum nitride. For example, the conductive bumps 110 are made of tin.

For example, the conductive bump 110 can be controlled collapse chip connection (C4), known for excellent electrical and thermal properties thereof. Under a similar pitch of the first conductive bumps, and I/O value of the conductive bump 110 can be very high and is not limited by a size of a rewiring structure. In addition, the conductive bumps 110 are suitable for mass production and greatly reduces the size and weight.

In other embodiments, the conductive bumps may also be micro-bumps (uBumps).

Specifically, referring to FIG. 14, as an example, in the embodiment, the conductive bumps 110 are formed on the front side 200a of the second chip of the device chip 200.

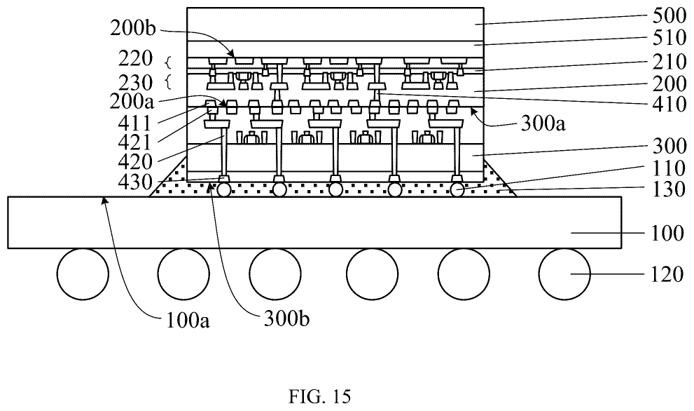

Referring to FIG. 15, the conductive bumps 110 are configured to bond the device chip 200 to the substrate 100, and the conductive bumps 110 are electrically connected to the device chip 200 and the substrate 100.

Referring to FIG. 15, after the device chip 200 is bonded to the substrate 100, the packaging method further includes: filling in gaps between adjacent conductive bumps 110 with a sealing layer 130 covering the conductive bumps 110.

The sealing layer 130 is configured to provide sealing between the device chip 200 and the substrate 100, as well as between the interconnection chip 300 and the substrate 100. The sealing layer 130 is further configured to seal the conductive bumps 110.

It should be noted that in an actual process, the embodiment is particularly applicable when a buried power rail (BPR) structure and a power delivery network (PDN) structure are used, which require high chip size and integration.

In the embodiment, the conductive bumps 110 described above are the first conductive bumps 110. The packaging method further includes forming second conductive bumps 120 on a surface of the substrate 100 facing away from the bonding surface 100a. The second conductive bumps 120 are configured to establish electrical connections between the packaging structure and the external circuit.

The electrical connections between the packaging structure and the external circuit are realized through the second conductive bumps 120, thereby establishing electrical connections between the device chip 200 and the interconnection chip 300 and the external circuit.

In the embodiment, a material of the second conductive bumps 120 includes one or more of tin, copper, aluminum, tungsten, cobalt, nickel, titanium, tantalum, titanium nitride and tantalum nitride. For example, the material of the second conductive bump 120 is tin.

For example, the second conductive e bump 120 can be controlled collapse chip connection (C4), known for excellent electrical and thermal properties thereof. Under a similar pitch of the second conductive bumps, and I/O value of the second conductive bump 120 can be very high and is not limited by a size of a rewiring structure. In addition, the second conductive bumps 120 are suitable for mass production and greatly reduces the size and weight.

In other embodiments, the second conductive bump may also be a ball grid array (BGA) structure.

As disclosed, the packaging structure and the packaging method provided by the present disclosure at least realize the following beneficial effects.

In the packaging structure, the interconnection chip is bonded to the bonding surface of the substrate. The interconnection chip includes the front side and the back side of the first chip opposite to each other. The back side of the first chip faces and is electrically connected to the substrate. The device chip is bonded to the interconnection chip. The device chip includes the front side and the back side of the second chip opposite to each other, the front side of the second chip faces and is electrically connected to the interconnection chip. The back side of the second chip is electrically connected to the interconnection chip through the front side of the second chip. In the embodiment of the present disclosure, the interconnection chip is bonded to the substrate to establish an electrical connection between the interconnection chip and the substrate. The front side of the second chip of the device chip is bonded to the interconnection chip to establish an electrical connection between the front side of the second chip of the device chip and the interconnection chip, and correspondingly establish an electrical connection between the front side of the second chip of the device chip and the substrate. The back side of the second chip is electrically connected to the interconnection chip through the front side of the second chip, so that the back side of the second chip of the device chip is electrically connected to the substrate, thereby enabling both the front side and the opposite back side of the second chip of the device chip to be electrically connected to the substrate. Therefore, through the substrate, the device chip can be powered through either or both front side and back side of the second chip, thereby improving the integration of the packaging structure. Simultaneously, the front side of the second chip and the front side of the first chip establish an electrical connection between the device chip 200 and the interconnection chip 300, thereby facilitating an easy bonding between the device chip and the interconnection chip and simplifying electrical connection lines.

The packaging method includes providing the interconnection chip, including the front side and the back side of the first chip opposite to each other; providing the device chip, including the front side and the back side of the second chip opposite to each other, bonding the device chip to the interconnection chip, the front side of the second chip facing and being electrically connected to the front side of the first chip, and the back side of the second chip being electrically connected to the interconnection chip through the front side of the second chip; and providing a substrate including a bonding surface, bonding the interconnection chip to the bonding surface of the substrate, and the back side of the first chip facing and being electrically connected to the substrate. In the embodiment of the present disclosure, the interconnection chip is bonded to the substrate to realize an electrical connection between the interconnection chip and the substrate. The front side of the second chip of the device chip is bonded to the interconnection chip to realize an electrical connection between the front side of the second chip of the device chip and the interconnection chip, and correspondingly establishes an electrical connection between the front side of the second chip of the device chip and the substrate. The back side of the second chip is electrically connected to the interconnection chip through the front side of the second chip, so that the back side of the second chip of the device chip is electrically connected to the substrate, thereby enabling both the front side and the opposite back side of the second chip of the device chip to be electrically connected to the substrate. Therefore, through the substrate, the device chip can be powered through either or both front side and back side of the second chip, thereby improving the integration of the packaging structure. Simultaneously, the front side of the second chip and the front side of the first chip establish an electrical connection between the device chip 200 and the interconnection chip 300, thereby facilitating an easy bonding between the device chip and the interconnection chip and simplifying electrical connection lines.

The present disclosure is disclosed above but is not limited thereto. A person skilled in the art can make various changes and modifications without departing from the spirit and scope of the present disclosure. The scope of protection of the present disclosure shall be determined by the scope defined in the claims.

What is claimed is:

1. A packaging structure, comprising:
a substrate, including a bonding surface;
an interconnection chip, bonded to the bonding surface of the substrate, the interconnection chip including a front side and a back side of a first chip opposite to each other, and the back side of the first chip facing and being electrically connected to the substrate; and
a device chip, bonded to the interconnection chip, the device chip including a front side and a back side of a second chip opposite to each other, the front side of the second chip facing and being electrically connected to the interconnection chip, and the back side of the second chip being electrically connected to the interconnection chip through the front side of the second chip.

2. The packaging structure according to claim 1, wherein devices the device chip are electrically connected to the back side of the second chip to supply power through the back side of the second chip.

3. The packaging structure according to claim 1, wherein the device chip includes a backside interconnection layer on the back side of the second chip, the backside interconnection layer is electrically connected to the interconnection chip, and the backside interconnection layer is further electrically connected to the devices on the device chip.

4. The packaging structure according to claim 3, wherein first interconnection structures are formed on the front side of the second chip of the device chip, and the backside interconnection layer of the device chip is electrically connected to the interconnection chip through the first interconnection structure.

5. The packaging structure according to claim 1, wherein first interconnection structures are formed on the front side of the second chip of the device chip, second interconnection structures penetrating the interconnection chip are formed on the interconnection chip, the second interconnection structures are electrically connected to the first interconnection structures, and the second interconnection structures are further electrically connected to the substrate.

6. The packaging structure according to claim 5, further comprising interconnection pads, on the backside of the first chip and electrically connected to the second interconnection structure.

7. The packaging structure according to claim 1, wherein first interconnection structures are formed on a front side of the second chip of the device chip, the first interconnection structures include first bonding pads exposed by the front side of the second chip, second interconnection structures penetrating the interconnection chip are formed on the interconnection chip, and a second interconnection structure of the second interconnection structures includes a second bonding pad exposed by the front side of the first chip, and the first bonding pads are bonded to the second bonding pads.

8. The packaging structure according to claim 1, further comprising a carrier board bonded to the back side of the second chip of the device chip.

9. The packaging structure according to claim 8, further comprising a bonding dielectric layer between the device chip and the carrier board, and the device chip and the carrier board being bonded through the bonding dielectric layer.

10. The packaging structure according to claim 1, further comprising conductive bumps between the interconnection chip and the substrate and being electrically connected to the interconnection chip and the substrate.

11. The packaging structure according to claim 1, further comprising a sealing layer filled in gaps between adjacent conductive bumps and covering the conductive bumps.

12. A packaging method, comprising:
providing an interconnection chip, including a front side and a back side of a first chip opposite to each other;
providing a device chip, including a front side and a back side of a second chip opposite to each other, bonding the device chip to the interconnection chip, the front side of the second chip facing and being electrically connected to the front side of the first chip, and the back side of the second chip being electrically connected to the interconnection chip through the front side of the second chip; and
providing a substrate including a bonding surface, bonding the interconnection chip to the bonding surface of the substrate, and the back side of the first chip facing and being electrically connected to the substrate.

13. The packaging method according to claim 12, wherein in the electrically connecting the back side of the second chip to the interconnection chip through the front side of the second chip, devices on the device chip are electrically connected to the back side of the second chip for supplying power to the devices on the device chip through the back side of the second chip.

14. The packaging method according to claim 12, wherein the electrically connecting the second chip backside to the interconnection chip through the second chip frontside includes:
after bonding the front side of the second chip of the device chip to the front side of the first chip of the interconnection chip, performing a backside thinning process on the device chip through the back side of the second chip; and
after performing the backside thinning process, forming a backside interconnection layer on the back side of the second chip, the backside interconnection layer being electrically connected to devices on the device chip, and the backside interconnection layer being also electrically connected to the interconnection chip.

15. The packaging method according to claim 14, wherein:
in providing the device chip, first interconnection structures are formed on the front side of the second chip of the device chip;
in bonding the device chip to the interconnection chip, the first interconnection structures are electrically connected to the interconnection chip; and
in forming a backside interconnection layer on the back side of the second chip, the backside interconnection layer is electrically connected to the first interconnection structures.

16. The packaging method according to claim 12, wherein:
in providing the interconnection chip, second interconnection structures are formed in the interconnection chip, and the second interconnection structure extends from the front side of the first chip to the back side of the first chip;
in providing the device chip, first interconnection structures are formed on the front side of the second chip in the device chip;
in bonding the device chip to the interconnection chip, the second interconnection structure is electrically connected to the first interconnection structure; and
in bonding the interconnection chip to the bonding surface of the substrate, the second interconnection structure is electrically connected to the substrate.

17. The packaging method according to claim 16, before the interconnection chip is bonded to the bonding surface of the substrate, further comprising forming interconnection pads on the back side of the first chip that are electrically connected to the second interconnection structures.

18. The forming method according to claim 17, wherein the forming interconnection pads electrically connected to internal interconnection structures on the back side of the first chip includes:
performing a backside thinning process on the back side of the first chip to expose the second interconnection structure; and
forming interconnection pads on an exposed surface of the second interconnection structure.

19. The packaging method according to claim 16, after the device chip is bonded to the interconnection chip, and the back side of the second chip is electrically connected to the interconnection chip through the front side of the second chip, and before the interconnection pads electrically connected to internal interconnection structures are formed on the back side of the first chip, further comprising providing a carrier board and bonding the carrier board to the back side of the second chip of the device chip.

20. The packaging method according to claim 12, wherein:
in providing the device chip, first interconnection structures are formed on a front side of the second chip of the device chip, and the first interconnection structures include first bonding pads exposed by the front side of the second chip;
in providing the interconnection chip, second interconnection structures are formed on the interconnection chip, internal interconnection structures extend from the front side of the first chip to the back side of the first chip, and the second interconnection structures include second bonding pads exposed by the front side of the first chip; and
in bonding the device chip to the interconnection chip, the first bonding pads are bonded to the second bonding pads.
